(19) United States
(12) Patent Application Publication
(10) Pub. No.: US 2009/0078304 A1
(43) Pub. Date: Mar. 26, 2009

(54) PHOTOVOLTAIC CHARGE ABATEMENT DEVICE, SYSTEM, AND METHOD

(76) Inventors: Jack Arthur Gilmore, Fort Collins, CO (US); Eric Seymour, Fort Collins, CO (US)

Correspondence Address: Neugeboren O''Dowd PC, 1227 Spruce Street, SUITE 200, BOULDER, CO, 80302, US

(21) Appl. No.: 11/861,881

(22) Filed: Sep. 26, 2007

(51) Int. Cl. H01L 31/042; H02M 7/537

(52) U.S. Cl. 136/248; 363/131

(57) ABSTRACT

A system, method and apparatus are disclosed for abating charge accumulation on a photovoltaic array. In one embodiment, the method includes arranging a portion of a photovoltaic array so that the portion of the photovoltaic array operates above a ground potential; converting solar energy into electrical energy with the photovoltaic array, wherein the portion of the photovoltaic array is predisposed to accumulate a charge on a surface of the portion of the photovoltaic array while the solar energy is converted to electrical energy; and abating charge accumulation on the surface of the portion of the photovoltaic array that operates above a ground potential.

### FIELD OF THE INVENTION

This invention relates generally to apparatus and methods for converting solar energy to electrical energy, and more specifically to apparatus and methods for more efficient conversion of solar energy to electrical energy.

### BACKGROUND OF THE INVENTION

The transformation of light energy into electrical energy using photovoltaic (PV) devices has been known for a long time and these photovoltaic devices are increasingly being implemented in residential, commercial, and industrial applications. Although developments and improvements have been made to these photovoltaic devices over the last few years to improve their efficiency, the efficiency of the photovoltaic devices is still a focal point for continuing to improve the economic viability of photovoltaic devices.

Photovoltaic modules are commonly connected with a negative lead of the PV tied to ground so that the module is put into operation at high positive voltages with respect to earth ground. In this type of configuration, however, it has been discovered that “surface polarization” of the module can occur. Surface polarization typically results in an accumulation of static charge on the surface of the solar cells.

In some solar panels, the front surface of the cells are coated with a material that can become charged. This layer performs much like the gate of a field-effect transistor. A negative charge at the surface of the solar cell increases hole-electron recombination When this happens, surface polarization reduces the output current of the cell.

Surface polarization can occur when a module is put into operation at high positive voltages. If the module is operated at a positive voltage with respect to the earth ground, for example, minute leakage current may flow from the cells of the module to ground. As a result, over time, a negative charge is left on the front surface of a cell. And this negative charge attracts positive charge (holes) from a bottom layer of the cell to the front surface where the holes recombine with electrons, and the holes are lost instead of collecting at the positive junction of the module. As a consequence, the current that is produced by the cell is reduced.

Although modules may be operated at negative voltage with respect to ground to prevent surface polarization, this type of architecture prevents bipolar inverters, or inverters with floating arrays, from being utilized because a portion of the photovoltaic array (typically one-half of the array) is operated above ground potential when a bipolar inverter is utilized. And bipolar inverters are typically more efficient than monopolar inverters, in part, because bipolar inverters may be operated at higher voltages, which reduces current losses. As a consequence, it would be beneficial to be able to efficiently utilize bipolar inverters, or inverters with floating arrays, in connection with photovoltaic modules without encountering the deleterious effects of charge accumulation on the photovoltaic modules.

### SUMMARY OF THE INVENTION

Exemplary embodiments of the present invention that are shown in the drawings are summarized below. These and other embodiments are more fully described in the Detailed Description section. It is to be understood, however, that there is no intention to limit the invention to the forms described in this Summary of the Invention or in the Detailed Description. One skilled in the art can recognize that there are numerous modifications, equivalents and alternative constructions that fall within the spirit and scope of the invention as expressed in the claims.

In one exemplary embodiment, the present invention can include a photovoltaic inverter that includes a first input configured to couple to a first rail of a photovoltaic array and second input configured to couple to a second rail of a photovoltaic array. In this embodiment, an inverter is coupled to the first and second inputs and the inverter is configured to convert DC power from the photovoltaic array to AC power. A power supply is configured to apply a negative potential with respect to a ground potential, and a third input is configured to couple to a portion of the photovoltaic array that is substantially at the positive potential. And a switch configured to couple the negative voltage to the third input so as to enable the portion of the photovoltaic array that is substantially at the positive potential to be placed at the negative potential.

In another embodiment, the invention may be characterized as a method comprising arranging a portion of a photovoltaic array so that the portion of the photovoltaic array operates above a ground potential, and converting solar energy into electrical energy with the photovoltaic array, wherein the portion of the photovoltaic array is predisposed to accumulate a charge on a surface of the portion of the photovoltaic array while the solar energy is converted to electrical energy. And in this embodiment charge accumulation is abated on the surface of the portion of the photovoltaic array that operates above a ground potential.

In yet another embodiment the invention may be characterized as a photovoltaic module comprising an energy conversion portion adapted to convert solar energy to electrical energy; a positive lead coupled to the energy conversion portion; a negative lead coupled to the energy conversion portion; and a conductor arranged in close proximity to the energy conversion portion so as to enable the conductor, when coupled to a positive potential relative to a potential of the negative lead, to repel positive charges away from a surface of the energy conversion portion.

As previously stated, the above-described embodiments and implementations are for illustration purposes only. Numerous other embodiments, implementations, and details of the invention are easily recognized by those of skill in the art from the following descriptions and claims.

### BRIEF DESCRIPTION OF THE DRAWINGS

Various objects and advantages and a more complete understanding of the present invention are apparent and more readily appreciated by reference to the following Detailed Description and to the appended claims when taken in conjunction with the accompanying Drawings wherein:

FIG. 1 is a block diagram depicting an exemplary embodiment of a power delivery system;

FIG. 2 is a block diagram depicting an exemplary embodiment in which the charge abatement portion depicted in FIG. 1 is realized by a negative power supply;

FIG. 3 is a block diagram depicting another embodiment in which the charge abatement portion depicted in FIG. 1 is realized, at least in part, by a negative power supply;

FIG. 4 is a block diagram depicting yet another embodiment of the present invention in which the charge abatement portion depicted in FIG. 1 is realized, at least in part, by a charged conductor;

FIG. 5 is block diagram depicting yet another embodiment in which the charge abatement portion depicted in FIG. 1 is realized, at least in part, by a charged conductor;

FIG. 6 is a partial and cut-a-way view of an exemplary embodiment of a photovoltaic module;

FIG. 7 is a schematic drawing depicting an exemplary photovoltaic assembly that includes a charged conductor;

FIG. 8 is a schematic view of yet another embodiment in which the charged conductors depicted in FIGS. 4 and 5 are realized by a charged conductor that is disposed upon a surface of a photovoltaic module; and

FIG. 9 is a flowchart depicting an exemplary method that may be carried out in connection with one or more of the embodiments described with reference to FIGS. 1-8.

### DETAILED DESCRIPTION

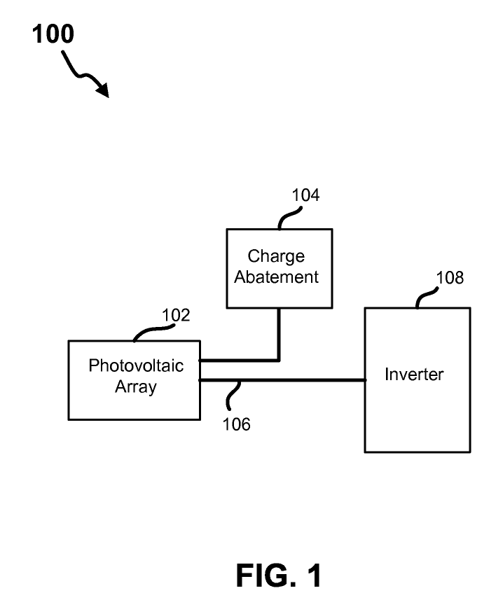

Referring now to the drawings, where like or similar elements are designated with identical reference numerals throughout the several views, and referring in particular to FIG. 1, it is a block diagram depicting a power delivery system 100 including a photovoltaic array 102 that is coupled to both a charge abatement portion 104 and in the inverter 108.

In general, the photovoltaic array 102 converts solar energy to DC electrical power, and applies the DC power to the inverter 108, which converts the DC power to AC power (e.g., three-phase power). The charge abatement portion 104 in this embodiment is configured to mitigate the adverse consequences of a charge (e.g., negative charge) that may accumulate on the surface of one or more modules of the photovoltaic array 102.

In many embodiments, the charge abatement portion 104 reduces an amount of surface charge that the photovoltaic array would ordinarily accumulate if the charge abatement portion 104 were not in place. In some embodiments for example, the charge abatement portion 104 prevents deleterious charges from building up the surface of one or more modules of the photovoltaic array 102 in the first place. And in other embodiments, the charge abatement portion 104 removes or reduces a charge that has accumulated on the surface of one or modules of the array 102.

It should be recognized that the block diagram depicted in FIG. 1 is merely logical. For example, the charge abatement portion 104 in some implementations is housed within the inverter 108, and in other implementations the charge abatement portion 104 is realized as a separate piece of hardware from the inverter and array 102. In yet other embodiments the charge abatement portion 104 is implemented in connection with the photovoltaic array 102 (e.g., integrated with or in close proximity to the array 102).

As discussed further herein, in some embodiments the photovoltaic array 102 is a bipolar array, and in many of these embodiments, at least a portion of the array 102 is disposed so as to operate at a positive voltage with respect to ground. But this is certainly not required, and in other embodiments the photovoltaic array 102 is a monopolar array, which in some variations operates at voltages substantially higher than ground.

In addition, one of ordinary skill in the art will appreciate that the photovoltaic array 102 may include a variety of different type photovoltaic cells that are disposed in a variety of different configurations. For example, the photovoltaic cells may be arranged in parallel, in series or a combination thereof. And the inverter may be realized by a variety of inverters. In some embodiments, for example, the inverter is a bipolar inverter (e.g., an inverter sold under the trade name SOLARON by Advanced Energy, Inc. of Fort Collins, Colo.), but this is certainly not required and in other embodiments, the inverter 108 realized by one or more of a variety of monopolar inverters, which are well known to one of ordinary skill.

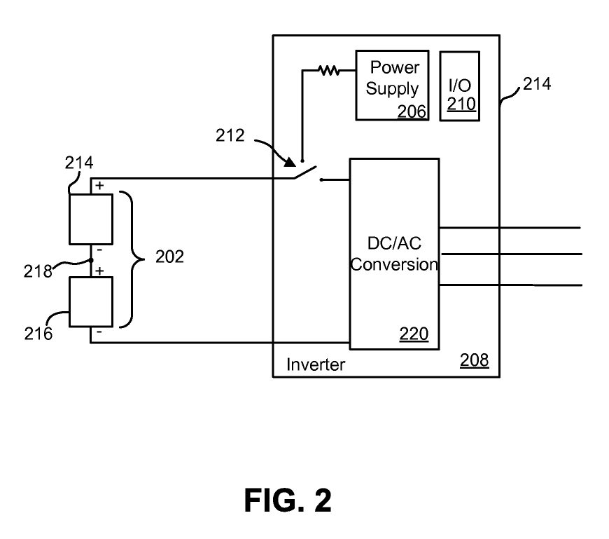

Referring next to FIG. 2, shown is a block diagram depicting an exemplary embodiment in which the charge abatement portion 104 depicted in FIG. 1 includes a negative power supply 206. As shown, a photovoltaic array 202 in this embodiment is coupled via switch 212 to the power supply 206, which resides within a housing 214 of an inverter 208. In addition, the array 202 is also coupled to a DC/AC conversion module 220, which is configured to convert DC power from the photovoltaic array 202 to AC power (e.g., 3-phase AC power).

Although not required, the photovoltaic array 202 in this embodiment is a bipolar array that includes a first portion 214 and a second portion 216 that are coupled at a node 218 that is near, or at, a ground potential. As a consequence, the first portion 214 of the array 202 operates above the ground potential and the second portion 216 of the array 202 operates below the ground potential. In many embodiments, each of the first and second portions 214, 216 of the photovoltaic array 202 includes several photovoltaic modules that may be arranged in series, parallel and/or series-parallel combinations.

In operation, before the photovoltaic array 202 begins applying power to the inverter 208 (e.g., before the sun rises), a negative voltage (e.g., −600 VDC) is applied by the power supply 206, via the switch 212, to a positive lead of the photovoltaic array 202. In this way, any negative charge that has accumulated on surfaces of the modules in the array 102 is swept away so that the array 202 is capable of operating at its nominal efficiency.

As a consequence, when the array 102 begins to convert solar energy to DC electrical energy (e.g., at sunrise), the array provides power more efficiently than it would with a negative charge accumulation. And in some embodiments, the remaining charge at the end of the day is still positive due to an accumulation of a positive charge attracted to a surface of the modules in the array 102 by the applied negative voltage at night.

In many embodiments, once the array 202 is no longer producing power (e.g., when the sun has set), the negative voltage is again applied to the positive lead of the array 202 to sweep the charge from the array 202. In this way, any reduced positive charge that has drained off the surface of one or more of the modules in array 102 is removed or substantially reduced, and the array 102 operates at an improved efficiency.

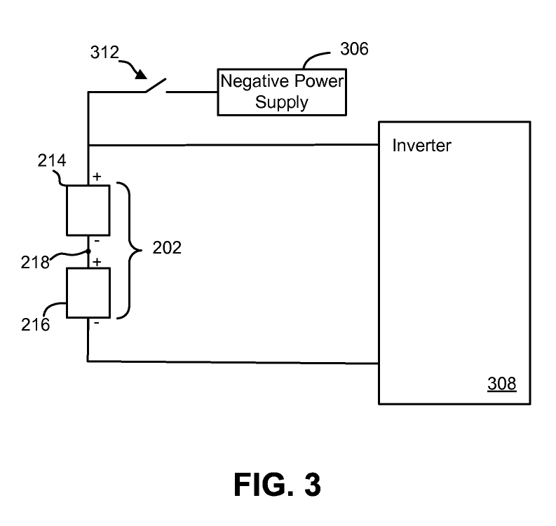

Referring next to FIG. 3, shown is a block diagram depicting another embodiment in which the charge abatement portion 104 depicted in FIG. 1 is realized, at least in part, by a negative power supply 306. As shown, this embodiment is similar to the embodiment described with reference to FIG. 2, but the power supply 306 in this embodiment is disposed externally to an inverter 308, so that, for example, the power supply 306 may be used in connection with an inverter already deployed (e.g., the power supply 306 may be implemented as a retrofit). In operation, the power supply 306 in this embodiment operates in substantially the same manner as the power supply 206 to sweep charge from the array 202.

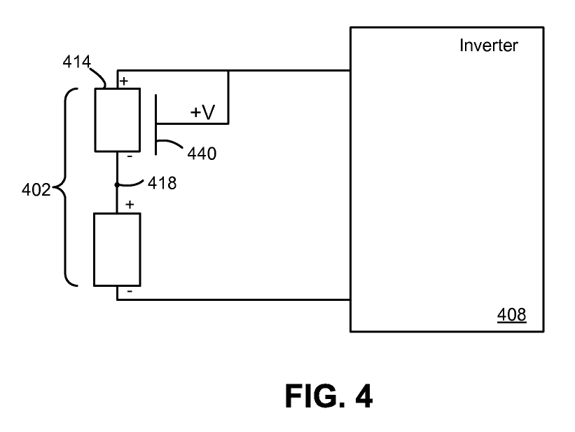

Referring next to FIG. 4, shown is a block diagram depicting yet another embodiment of the present invention in which the charge abatement portion 104 depicted in FIG. 1 is realized, at least in part, by a charged conductor 440. As shown, a conductor 440 is coupled to positive lead of a photovoltaic array 402 and disposed in close proximity to a surface of one or more modules of a first portion 414 of the photovoltaic array 404 that operates at positive voltage with respect to ground 418. As a consequence, the positive charge of the conductor 440 repels positive holes that would ordinarily be attracted to a surface of the module so the holes are eventually collected at the positive junction. As a consequence, the current reduction ordinarily experienced (due to hole recombination with negative charges resident on the front surface of the cell) is abated.

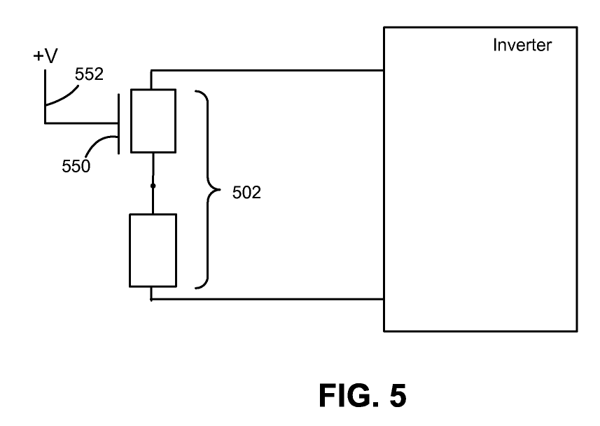

Referring next to FIG. 5 shown is block diagram depicting yet another embodiment in which the charge abatement portion depicted in FIG. 1 is realized, at least in part, by a charged conductor 550. As shown, this embodiment is similar to the embodiment described with reference to FIG. 4, but a charged conductor 550 is tied to a positive potential 552 that is separate from the positive lead of the array 502. In one embodiment, the positive potential is 1000 VDC, but this is certainly not required, and in other embodiments the positive potential that is applied to the conductor is one or more other voltages (e.g., 500 VDC).

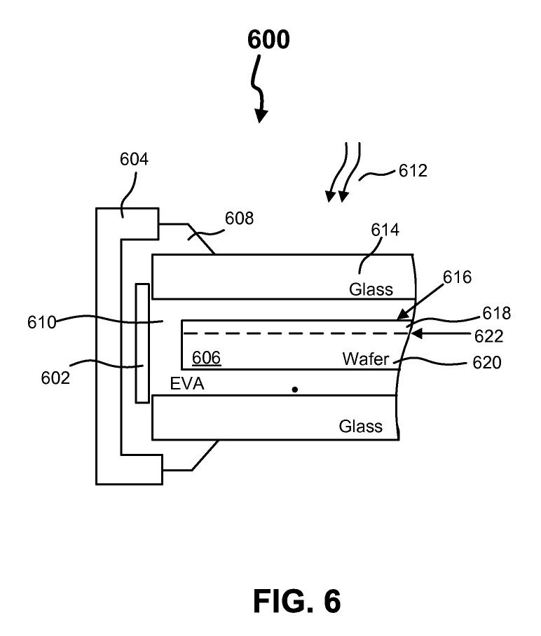

Referring next to FIG. 6 shown in is a partial and cut-a-way view of an exemplary embodiment of a photovoltaic module 600. As shown, in this embodiment the conductors 440, 550 described with reference to FIGS. 4 and 5, respectively, are realized by a conductive ring 602 (e.g., a guard ring) interposed between a frame 604 and a wafer 606 of the module 600. As depicted, the wafer in this embodiment includes a top layer 618 (e.g., a P-type material) and a bottom layer 620 (e.g., an N-type material) that meet at junction 622. As shown, the frame 604 is coupled to an insulator 608 (e.g., rubber) and the ring 602 is interposed between the insulator 608 and an ethyl vinyl acetate (EVA) layer 610, which surrounds the wafer 606.

In this embodiment, while solar energy 612 is imparted to the wafer 606 through a glass layer 614 and the EVA 610, the positive potential of the ring 602 conducts through the EVA 610 or on the inner or outer surface of the glass cover 614 so as to place a positive charge upon the EVA 610, which repels positive charges that would ordinarily be attracted from the bottom layer 620 to the top layer 618 so the positive charges are guided back to the collecting junction in the bottom layer 620 instead of being lost by recombination with negative charges at or near the surface 616 of the top layer 618.

Although not depicted in FIG. 6, in one embodiment a lead is coupled to the ring and disposed through the insulator 608 so as to allow the ring 602 to be coupled to a positive potential (e.g., potential 552). In another embodiment, the ring is conductively coupled to a positive lead of the module. Although not required, the ring in some embodiments is realized by a conductive tape (e.g., aluminum, tinned copper, and/or lead) that is placed around a periphery of the EVA 610 and separated from the frame 604 by the insulator 608.

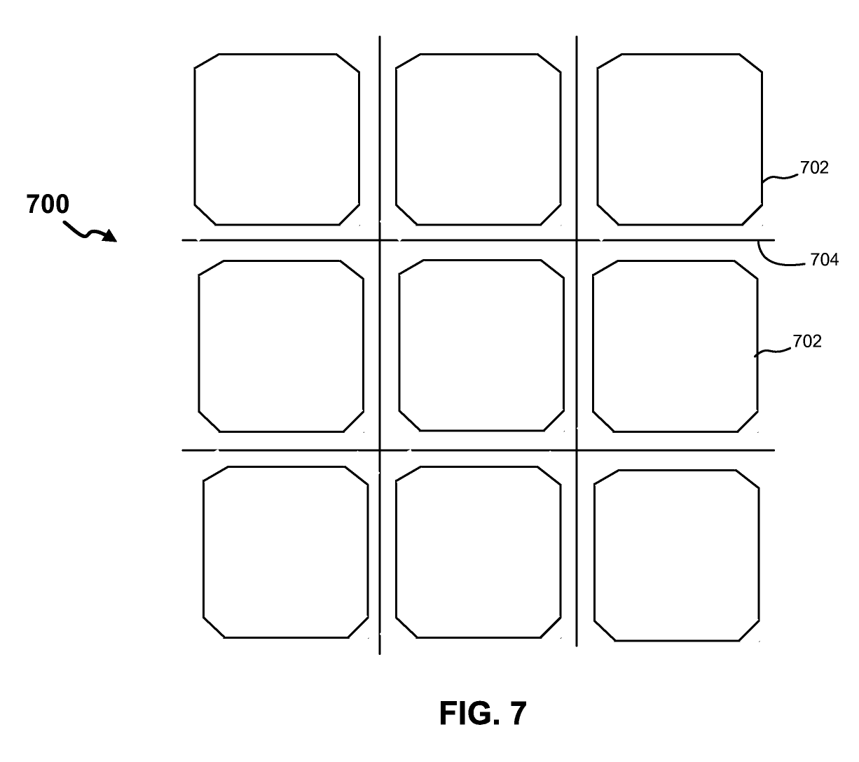

Referring next to FIG. 7, it is a schematic drawing depicting a photovoltaic assembly 700 that includes collection of photovoltaic modules 702 and a charged conductor 704 that is arranged so as to surround each module 702 while being interposed between the modules 702. In this embodiment, the conductors 440, 550 described with reference to FIGS. 4 and 5 are realized by the charged conductor 704, and as a consequence, in one embodiment, the charged conductor 704 is coupled to a positive lead from the collection of the modules, and in another embodiment, the charged conductor is coupled to a separate positive potential (e.g., potential 552).

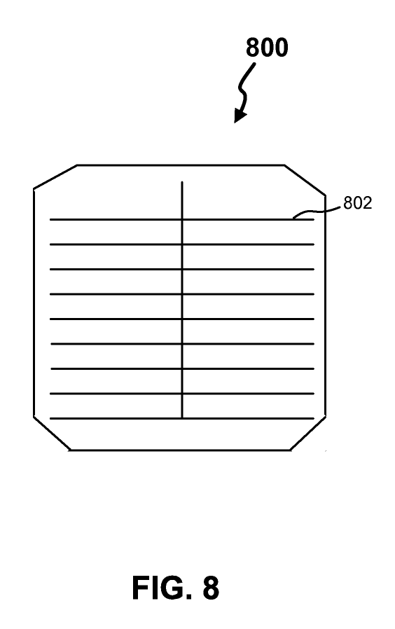

Referring to FIG. 8, shown is a schematic view of yet another embodiment in which the conductors 440, 550 described with reference to FIGS. 4 and 5 are realized by a charged conductor 802 that is insulated from current-carrying collection electrodes (not shown) and is disposed upon a surface of a module 800. As depicted, the conductor 802 includes a collection of connected linear conductors that are disposed about a surface of the module 800. In some embodiments, the conductor 802 is placed between a glass layer (e.g., glass layer 614) and an EVA layer (e.g., EVA layer 610). In other embodiments, the conductor 802 is placed upon a surface of the wafer (e.g., by deposition). In yet other embodiments, the conductor 802 is realized by a transparent conductive layer on the inner surface of the glass layer 614. These embodiments are merely exemplary, however, and it is contemplated that the conductor 802 may be disposed in a variety of positions within the module 802, and the conductor 802 may be arranged in a variety of architectural patterns.

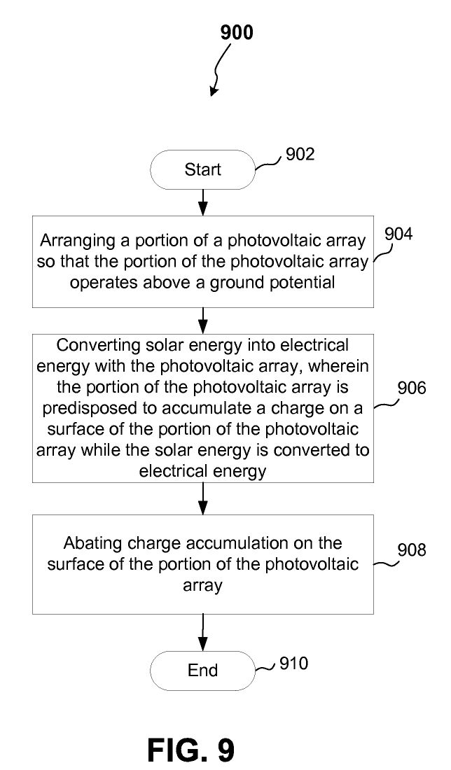

Referring next to FIG. 9, shown is a flowchart depicting an exemplary method that may be carried out in connection with one or more of the embodiments described with reference to FIGS. 1-8. As shown, a portion of the photovoltaic array is arranged so that it operates above ground potential (Blocks 902, 904). In some embodiments, the entire array (e.g., a monopolar array) is operated above ground potential (e.g., the array is negatively grounded), and in other embodiments a first portion of the array is negatively grounded and a second portion of the array is positively grounded so that the first portion of the array operates above ground potential and the second portion of the array operates below ground potential (e.g., a bipolar array).

As depicted in FIG. 9, solar energy is then converted into electrical energy with the photovoltaic array (Block 906). As discussed, many photovoltaic modules are predisposed to accumulating a charge (e.g., negative charge) on the surface of the module when operating above ground potential, which leads to a degradation in the efficiency of the module. To mitigate against any adverse effects of charge accumulation, the accumulation of charge on the surface of photovoltaic modules is abated (Blocks 908, 910).

As discussed with reference to FIGS. 2 and 3, the accumulation of charge in some embodiments is abated by coupling a positive lead of the photovoltaic array to a negative power supply while the array is offline so as to remove any accumulated negative charge from the array. And in some instances, the negative potential is utilized to accumulate a positive charge on the array so that during subsequent operation, when the array is converting solar energy to electrical energy, any negative charge accumulation during operation is substantially delayed relative to an amount of time that a comparable amount of charge accumulates on an array that is placed in operation without being preconditioned with a negative potential. Moreover, in other embodiments, a portion of the positive charge accumulated during the previous night still remains at the surface of the modules at the end of the day.

In other embodiments discussed with reference to FIGS. 4-8, the adverse effects of an accumulation of charge at the surface of the modules is abated by placing a positive potential in close proximity to a surface of the array so as to reduce or prevent an amount of positive charges, originating from a bottom portion of the modules, from combining with negative charges on the surface of the array.

In conclusion, the present invention provides, among other things, a system and method for improving operation of a photovoltaic array. Those skilled in the art can readily recognize that numerous variations and substitutions may be made in the invention, its use and its configuration to achieve substantially the same results as achieved by the embodiments described herein. Accordingly, there is no intention to limit the invention to the disclosed exemplary forms. Many variations, modifications and alternative constructions fall within the scope and spirit of the disclosed invention as expressed in the claims. For example, it is contemplated that yet other embodiments incorporate more than one of the embodiments depicted in FIGS. 2-8. In many embodiments for example, a negative power supply is utilized at night to remove any negative charge that may have accumulated on the array, and during the day, a positive potential is placed within, or in close proximity to, a surface of at least a portion of the array so as to reduce or prevent charge accumulation.

Moreover, one of ordinary skill in the art will appreciate that if the structure of the photovoltaic cell is reversed from the exemplary embodiments discussed in FIGS. 1-9, a positive voltage may be applied to a negative terminal of the module at night (instead of a negative voltage being applied to a positive terminal) to sweep positive charges from a surface of the module, and a negative potential may be applied to a charged conductor during the day to prevent electrons from being attracted to (and lost) a positive charge accumulation at a surface of the modules.

1. A photovoltaic inverter comprising:
a first input configured to couple to a positive rail of a photovoltaic array and second input configured to couple to a second rail of the photovoltaic array;
a conversion module coupled to the first and second inputs, the conversion module configured to convert DC power from the photovoltaic array to AC power;
a power supply configured to apply a negative potential with respect to a ground potential; and
a switch configured to couple the power supply to the positive rail so as to enable a portion of the photovoltaic array that is substantially at a positive potential to be placed at the negative potential.

2. The photovoltaic inverter of claim 1, wherein the second rail of the photovoltaic array is at a negative potential with respect to ground potential.

3. The photovoltaic inverter of claim 1, wherein the second rail of the photovoltaic array is at the ground potential.

4. The photovoltaic inverter of claim 1, wherein the conversion module converts the DC power to AC power without a transformer.

5. The photovoltaic inverter of claim 1, wherein the conversion module is configured to convert the DC power from the photovoltaic array to three-phase 480 Volts AC power.

6. A method comprising:
arranging a portion of a photovoltaic array so that the portion of the photovoltaic array operates above a ground potential;
converting solar energy into electrical energy with the photovoltaic array, wherein the portion of the photovoltaic array is predisposed to accumulate a charge on a surface of the portion of the photovoltaic array while the solar energy is converted to electrical energy; and
abating charge accumulation on the surface of the portion of the photovoltaic array that operates above a ground potential.

7. The method of claim 6, wherein the arranging includes arranging another portion of the photovoltaic array below the ground potential.

8. The method of claim 6, wherein abating charge accumulation includes reducing an amount of accumulated charge relative to an amount of charge the portion of the photovoltaic array is predisposed to accumulate while the solar energy is converted to electrical energy.

9. The method of claim 8, wherein reducing the amount of accumulated charge includes placing a positive potential adjacent to the portion of the photovoltaic array that operates above the ground potential.

10. The method of claim 9, wherein placing a positive potential includes placing a potential of a positive rail of the photovoltaic array adjacent to the portion of the photovoltaic array that operates above the ground potential.

11. The method of claim 9, wherein placing a positive potential includes placing, adjacent to the portion of the photovoltaic array that operates above the ground potential, a potential that is substantially higher than a potential of a positive rail of the photovoltaic array.

12. The method of claim 8, wherein abating charge accumulation includes removing a charge accumulation from the portion of the photovoltaic array while the photovoltaic array is not converting solar energy into electrical energy.

13. The method of claim 12, wherein removing a charge accumulation includes placing a negative voltage at a positive lead of the portion of the photovoltaic array that operates above the ground potential.

14. A photovoltaic module comprising:
an energy conversion portion adapted to convert solar energy to electrical energy, the energy conversion portion including a top layer and a bottom layer;
a positive lead coupled to the energy conversion portion;
a negative lead coupled to the energy conversion portion; and
a conductor arranged in close proximity to the energy conversion portion so as to enable the conductor, when coupled to a potential that is at least as positive as a potential of the positive lead, to repel positive charges away from a top layer within the energy conversion portion.

15. The photovoltaic module of claim 14 including:
a third lead coupled to the conductor so as to enable the conductor to be coupled to a potential that is greater than the potential of the positive lead.

16. The photovoltaic module of claim 14, wherein the conductor includes a ring disposed about a perimeter of the energy conversion portion.

17. The photovoltaic module of claim 14, wherein the conductor includes a collection of conductors disposed about a face of the energy conversion portion.

18. A system comprising:
a photovoltaic array arranged so that a portion of the photovoltaic array operates above a ground potential; and
a charge abating portion coupled to the photovoltaic array that is configured to abate charge accumulation on the surface of the portion of the photovoltaic array that operates above a ground potential.

19. The system of claim 18, wherein the charge abating portion includes a negative power supply switchably coupled to a positive lead of the photovoltaic array.

20. The system of claim 19, wherein the negative power supply is housed within an inverter.

21. The system of claim 18, wherein the charge abating portion includes a conductor coupled to a positive potential relative to the ground potential, wherein the conductor is in close proximity to a surface of the photovoltaic array so as to abate a combination of positive charges with negative charges on the surface of the photovoltaic array.
